(19) United States
(12) Patent Application Publication
(10) Pub. No.: US 2013/0234087 A1
(43) Pub. Date: Sep. 12, 2013

(54) NON-VOLATILE RESISTANCE CHANGE DEVICE

(71) Applicants: Takashi Yamauchi, Kanagawa-ken (JP); Yoshifumi Nishi, Niigata-ken (JP); Jiezhi Chen, Kanagawa-ken (JP); Akira Takashima, Tokyo (JP); Minoru Amano, Kanagawa-ken (JP)

(72) Inventors: Takashi Yamauchi, Kanagawa-ken (JP); Yoshifumi Nishi, Niigata-ken (JP); Jiezhi Chen, Kanagawa-ken (JP); Akira Takashima, Tokyo (JP); Minoru Amano, Kanagawa-ken (JP)

(73) Assignee: KABUSHIKI KAISHA TOSHIBA, Tokyo (JP)

(21) Appl. No.: 13/605,917

(22) Filed: Sep. 6, 2012

(30) Foreign Application Priority Data
Mar. 6, 2012 (JP) P2012-049634

(51) Int. Cl. H01L 45/00

(52) U.S. Cl. 257/1; 257/E45.002

(57) ABSTRACT

A non-volatile resistance change device includes a first electrode made of a metallic element, a second electrode, a variable resistance layer formed between the first electrode and the second electrode, first wiring formed on the first electrode on a side opposite to the variable resistance layer, and second wiring formed on the second electrode on a side opposite to the variable resistance layer. If the width of the first wiring is represented as A (nm), the width of the second wiring represented as B (nm), and the distance between the first electrode and the second electrode represented as L₀ (nm), the following equation is satisfied:

$$\frac{\sqrt{3}}{2} \sqrt{AB} < {L}_{0} \leq 6.7 .$$

### CROSS-REFERENCE TO RELATED APPLICATION

This application is based upon and claims the benefit of priority from Japanese Patent Application No. 2012-049634, filed Mar. 6, 2012; the entire contents of which are incorporated herein by reference.

### FIELD

Embodiments described herein relate to a non-volatile resistance change device.

### BACKGROUND

A non-volatile resistance change device which causes a large change in resistance against voltage does not need equipment that which apply a magnetic field, etc., making it possible for the entire device to be made smaller, and has been reported to be useful in applications. This non-volatile resistance change device uses an amorphous silicon layer (referred to as amorphous silicon layer, or, in its abbreviated form, as a-Si layer from here on) in a rheostat, making high speed operation possible at low voltages. It is expected that this non-volatile resistance change device varies the resistance in a manner that is reversible by creating and destroying a conductive filament in the amorphous silicon layer.

In order to improve the reliability of operations by, for example, providing consistent operational characteristics etc. when applied as a switching device, it is necessary to improve the stability of the conductive filament formed in the amorphous silicon layer. However, experimental observations of the structure of the conductive filament formed in the amorphous silicon layer have not been reported, so the structure of the conductive filament is still not clear.

Consequently, in order to improve the characteristics of this non-volatile resistance change device, along with making the structure of the conductive filament more precise, it is necessary to implement a structural design based on a physical model current of the conductive filament. However, there has been no report of this kind of physical model.

### DESCRIPTION OF THE DRAWINGS

FIG. 1 is a cross-sectional diagram showing a non-volatile resistance change device.

FIG. 2A to FIG. 2D are cross-sectional diagrams showing operating principles of the non-volatile resistance change device.

FIG. 3A to FIG. 3C are schematic diagrams describing physical phenomena associated with the non-volatile resistance change device.

FIG. 4A to FIG. 4C are schematic diagrams describing physical phenomena associated with the non-volatile resistance change device.

FIG. 5 shows the atomic structure of the Ag filament in the non-volatile resistance change device.

FIG. 6 shows the calculation results of the current-voltage characteristics in the non-volatile resistance change device.

FIG. 7 is a schematic diagram of the Ag filament formed within the variable resistance layer of the non-volatile resistance change device.

FIG. 8 is a schematic diagram showing the ideal Ag filament formation within the variable resistance layer of the non-volatile resistance change device.

FIG. 9 is a schematic diagram showing the Ag cluster formation within the variable resistance change layer of the non-volatile resistance change device.

FIG. 10 shows the relationship between the switching speeds and operating voltages of the non-volatile resistance change device.

FIG. 11A and FIG. 11B are figures showing the relationship between the wiring and the non-volatile resistance change device.

FIG. 12 is a cross-sectional diagram of the non-volatile resistance change device according to a first embodiment.

FIG. 13 is a cross-sectional diagram of the non-volatile resistance change device according to a second embodiment.

FIG. 14 is a cross-sectional diagram of the non-volatile resistance change device according to a third embodiment.

FIG. 15 is a cross-sectional diagram of the non-volatile resistance change device according to a fourth embodiment.

FIG. 16 is a cross-sectional diagram showing the production process of the non-volatile resistance change device according to the fourth embodiment.

FIG. 17 is a perspective diagram showing the production process of the non-volatile resistance change device according to the fourth embodiment.

FIG. 18 is a perspective diagram showing the production process of the non-volatile resistance change device according to the fourth embodiment.

FIG. 19 is a perspective diagram showing the production process of the non-volatile resistance change device according to the fourth embodiment.

FIG. 20 is a perspective diagram showing the production process of the non-volatile resistance change device according to the fourth embodiment.

FIG. 21 is a perspective diagram showing the production process of the non-volatile resistance change device according to the fourth embodiment.

FIG. 22 is a perspective diagram showing the production process of the non-volatile resistance change device according to the fourth embodiment.

FIG. 23 top view diagram showing the production process of the non-volatile resistance change device according to the fourth embodiment.

FIG. 24A and FIG. 24B are top view diagrams showing the manufacturing process of the non-volatile resistance change device according to the fourth embodiment.

FIG. 25 is a cross-sectional diagram of the non-volatile resistance change device according to a fifth embodiment.

FIG. 26A and FIG. 26B are figures showing a memory which utilizes the non-volatile resistance change device, according to a sixth embodiment.

### DETAILED DESCRIPTION

In general, embodiments are described below with references to the diagrams. The embodiments provide a non-volatile resistance change device in which a highly reliable switching operation is possible.

A non-volatile resistance change device according to an embodiment includes a first electrode which includes a metallic element, a second electrode, a variable resistance layer provided in the space between the first electrode and the second electrode, a first wiring that is provided on the first electrode on a side opposite the variable resistance layer and a second wiring that is provided on the second electrode on a side opposite to the variable resistance layer. The device satisfies the following formula when the width of the first electrode is A (nm), the width of the second electrode is B (nm) and the distance between the first electrode and the second electrode is L₀ (nm):

$$\frac{\sqrt{3}}{2} \sqrt{AB} < {L}_{0} \leq 6.7$$

First, before describing the embodiments, the circumstances that led to the embodiments will be described.

Recently, the results of the experiment in which silver sulfide is used in the variable resistance change layer were reported (e.g., Refer to IEEE EDL Vol. 32. No. 7, July (2011)). In that report, it was proven that the conductive filament has a complex dendrite structure. This kind of structure of the conductive filament not only decreases the switching speeds of the non-volatile resistance change device considerably, but it is also evident that it decreases the reliability of the operation.

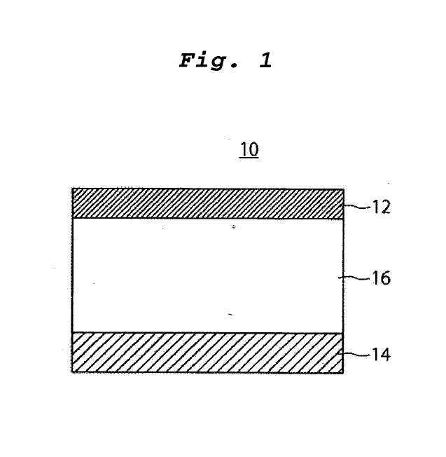

In general, as shown in FIG. 1, the non-volatile resistance change device 10 includes a first electrode 12 which has metal atoms, a second electrode 14 facing the first electrode 12, and a variable resistance layer 16 formed between the first electrode 12 and second electrode 14. For example, an Ag electrode may be used as the first electrode 12, a p-type Si (p-Si) electrode may be used as the second electrode 14 and an amorphous silicon layer may be used as the variable resistance layer 16.

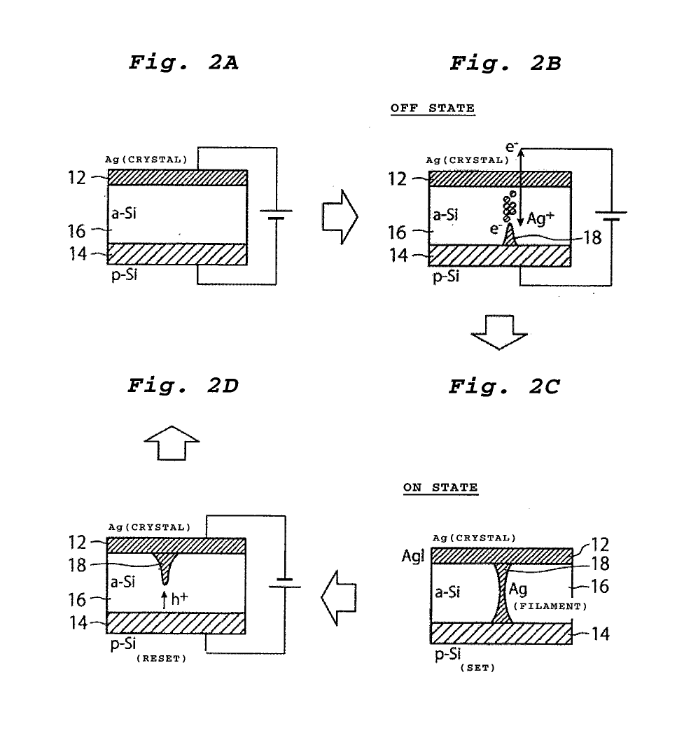

The physical phenomena occurring in these types of non-volatile resistance change devices will be described in detail by referring to FIG. 2A to FIG. 2D. Assuming an example case in which the first electrode 12 is an Ag electrode and the second electrode 14 is a p-Si electrode (FIG. 2A), if a positive voltage is applied across the first electrode 12 and the second electrode 14, decomposition and ionization of Ag metal atoms in the first electrode 12 occurs and the Ag ions that are formed flow towards the p-Si second electrode 14. In this state, connection between the Ag electrode 12 and p-Si electrode 14 through an Ag filament 18 does not occur, and the variable resistance layer 16 is in a state of high resistance. This state is called the OFF state (FIG. 2B).

Furthermore, if the applied voltage is increased so as to be approximately 5 V (first cycle), the connection of the Ag filament 18 occurs and there is a sudden drop in resistance. This state is called the ON state (SET State), and the process of applying voltage prior to the ON state occurring is called the SET Process (FIGS. 2A through 2C). Next, if the voltage applied across Ag electrode 12 and p-Si second electrode 14 is changed from a positive voltage to a negative voltage, the Ag Filament 18 is destroyed due to a reverse reaction, and the original state (RESET state) is restored (FIG. 2D). This voltage application process is called the RESET process (FIG. 2D).

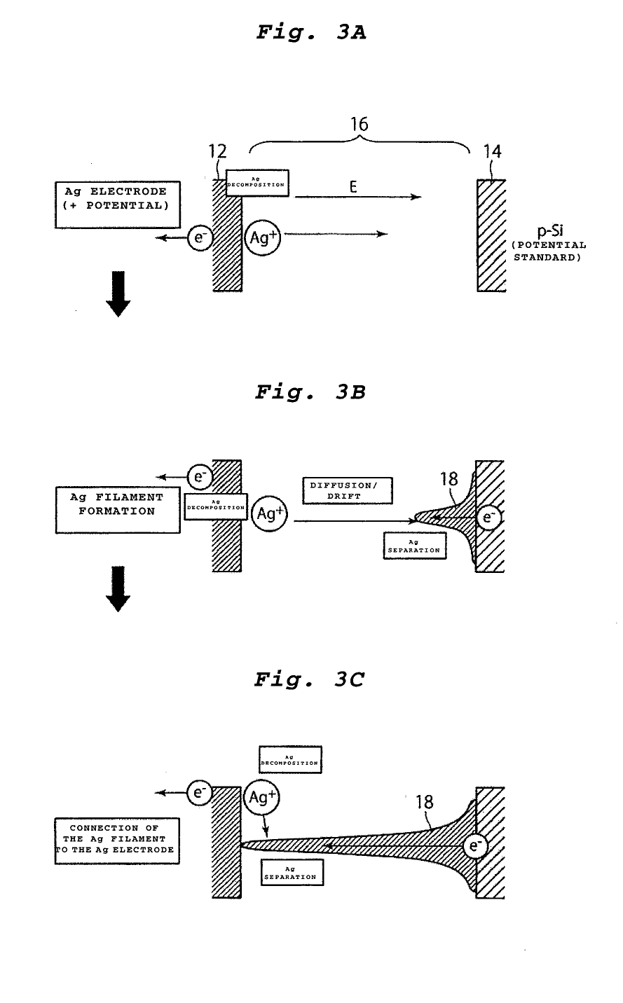

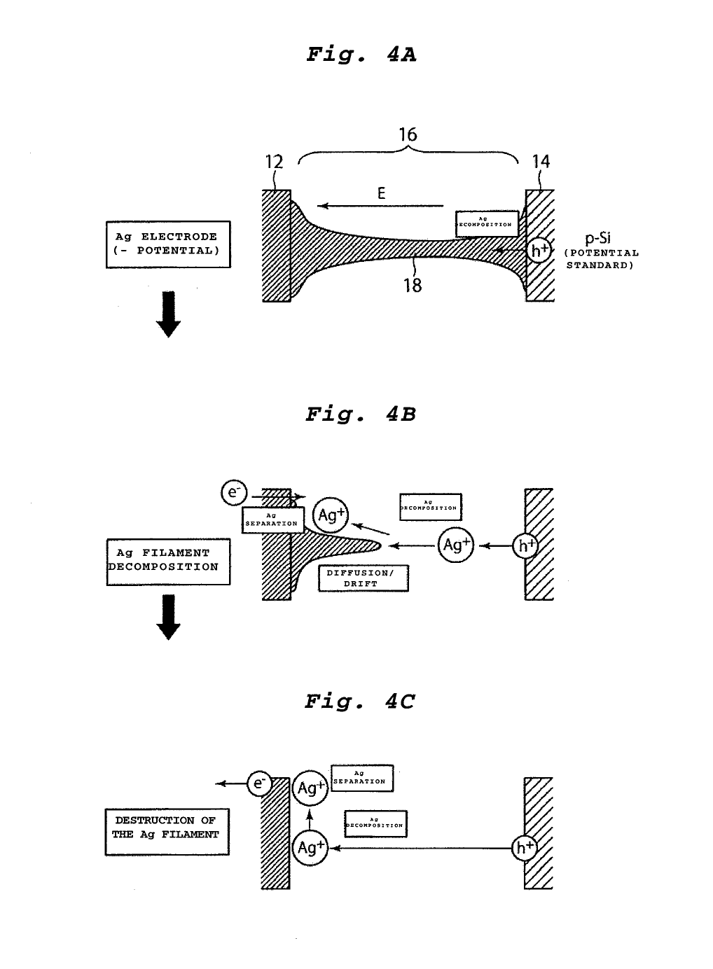

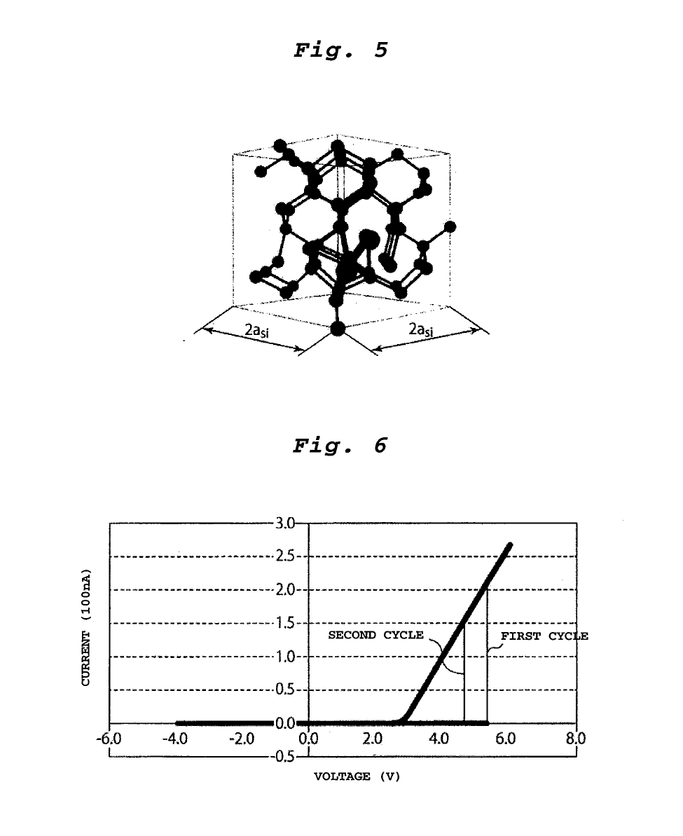

It is expected that, in the SET process, the transfer of Ag ions occurs as shown in FIG. 3A to FIG. 3C and the mass transfer associated with the RESET process occurs as shown in FIG. 4A to FIG. 4C. In the SET process, the initial stages of which are shown in FIG. 3A, if a positive voltage across the Ag electrode 12 and p-Si electrode 14, the Ag atoms inside the Ag electrode 12 disintegrate into Ag ions and electrons. At this time, an electric field is generated in the variable resistance layer 16. The fields directed from the Ag electrode 12 towards the p-Si electrode 14. The Ag ions generated by disintegration diffuse and drift inside the variable resistance layer 16 due to the electric field. Then, some of the Ag ions arrive at the p-Si electrode 14; when these Ag ions encounter electrons from the p-Si electrode 14, a filament of Ag atoms 18 is formed at the p-Si electrode 14 side (FIG. 3B). After that, if positive voltage is continued to be applied (and increased beyond a threshold), the filament of Ag atoms 18 grows and connects to the Ag electrode 12 (FIG. 3C). During this process, the Ag ions within the variable resistance layer 16 including amorphous silicon are unstable and exist in isolation.

Initially, in the RESET process, as shown in FIG. 4A, if a negative voltage is applied across the Ag electrode 12 and the p-Si electrode 14 while the filament 18 is connected to the Ag electrode, holes are released from the p-Si electrode 14 into the variable resistance layer 16. At this time, an electric field is formed in the variable resistance layer 16. The electric field is oriented in the direction from the p-Si electrode 14 toward the Ag electrode 12. The released holes scatter due to the electric field and disintegrates and ionizes the Ag atoms within the filament 18 so that they become Ag ions. The resulting Ag ions arrive at the Ag electrode 12 after drifting within the variable resistance layer 16, resulting in Ag being deposited at the Ag electrode 12. This process ruptures the previous connection between to the Ag electrode 12 and the p-Si electrode 14 (FIG. 4B) which the filament 18 had provided. After that, if negative voltage continues to be applied, the filament of Ag atoms 18 is entirely destroyed (FIG. 4C).

The electrode reactions in the SET process and RESET process are described by the Butler-Volmer equation as shown below:

$$J = 2 {J}_{0} sinh ( \frac{{q}_{ɛ} {Δη}_{1}}{2 {k}_{B} T} ) = {q}_{ɛ} {c}_{{Ag}^{+}} {μ}_{{Ag}^{+}} E \qquad ( 1 )$$

Here, J₀ is known as the exchange current density, and is a parameter that represents the reaction rate of the first and second electrode. Also, Δη₁ is known as the over-potential for producing an electrode reaction, and is the voltage necessary for overcoming the activation energy of the electrode reaction. J is the current density of the current flowing in the electrodes, k_{B} is the Boltzmann constant (1.3807×10⁻²³ J/K), T is the ambient absolute temperature (e.g., 300 K), qₑ is the electron charge (=1.6022×10⁻¹⁹ C), C_{Ag+} represents the concentration of the Ag ions inside the variable resistance layer, μ_{Ag+} represents the mobility of the Ag ions inside the variable resistance layer, and E represents the strength of the electric field applied to the electrodes.

Moreover, the length L(t) of the Ag filament 18 formed within the amorphous silicon is expected to grow in proportion to the electrode reaction, and the change in length is governed by the following differential equation:

$$\frac{d L ( t )}{d t} \approx \frac{1}{{ρ}_{Ag} {q}_{ɛ}} {F}_{f} J 0 \leq L ( t ) < {L}_{0} \qquad ( 2 )$$

In equation (2), the distance between the first and second electrode is L₀ and the density of the Ag filament 18 is ρ_{u Ag} (=6.2×10²¹ cm⁻³). The density of this Ag filament 18 is equivalent to the Ag density of a crystalline structure known to possess a metallic nature, based on the first principle calculation (FIG. 5). FIG. 5 shows the bonded state of the Ag atoms, when 8 Ag atoms are inserted into a 64-atom Si crystal lattice. In FIG. 5, a_{Si} represents the lattice constant of silicon. Also, if S_{f} is the effective cross-sectional area of the electrode reaction, and S denotes the surface area of the electrode on the surface facing the variable resistance layer, then F_{f}, the normalized active reaction area (dimensionless) is determined by the following equation:

$${F}_{f} = \frac{{S}_{f}}{S} \qquad ( 3 )$$

Additionally, the voltage drop Δη₂ that exists across the first and second electrode figures in the following equation involving the conductivity of Ag ions σ_{Ag}⁺ within amorphous silicon, the conductivity of the silver filament σ_{Ag} (=minimum metal conductivity ≈2.84×10² Ω⁻¹cm⁻¹) and the conductivity of the electrons σₑ (=6.2×10⁻⁷ Ω⁻¹cm⁻¹) within amorphous silicon

$${Δη}_{2} = \{ \begin{matrix}( \frac{{L}_{0} - L ( t )}{{σ}_{{Ag}^{+}}} + \frac{L ( t )}{{σ}_{Ag}} \frac{1}{{F}_{f}} ) J & ( set ) \\ ( \frac{{L}_{0} - L ( t )}{{σ}_{e}} + \frac{L ( t )}{{σ}_{{Ag}^{+}}} ) J & ( reset )\end{matrix} \qquad ( 4 )$$

In the two formulas given above, the formula at the top relates to the SET state and the formula at the bottom relates to the RESET state. Additionally, the sum of the over-potential Δη₁ and voltage drop Δη₂ will be equal to the voltage applied between the electrodes (t). Also, the flow of current through the electrodes is assumed to be the current due to the electrode reaction which flows in the areas (Area related to F_{f}) where the electrode reaction is occurring, and in the rest of the areas the normal electron conduction of amorphous silicon occurs.

Also, I_{comp} is known as compliance current, and represents the maximum value of the operating current. The compliance current is given by the following equation:

V(t)=Δη₁+Δη₂

I=S(F_{f}J+(1−F_{f})qₑσₑV(t)/L)≦I_{comp} (5)

Here, using electrodes having area (S) is 50 nm×50 nm, setting a distance between electrodes of 80 nm and with F_{f}, u_{Ag}⁺ and Jₒ set to have the following values, the results shown in FIG. 6 have been experimentally obtained. The results shown in FIG. 6 validate the experimental results documented in non-patent document 1.

F_{f}≈0.01

μ_{Ag}_{⁺}≈5×10⁻⁷ cm²/V sec

J₀≈9.4×10⁻²⁰ A/cm² (6)

From the obtained results, it can be estimated that about 1% of surface area of the second electrode participates effectively in the reaction, and that reaction area S_{f} is about 25 nm̂2.

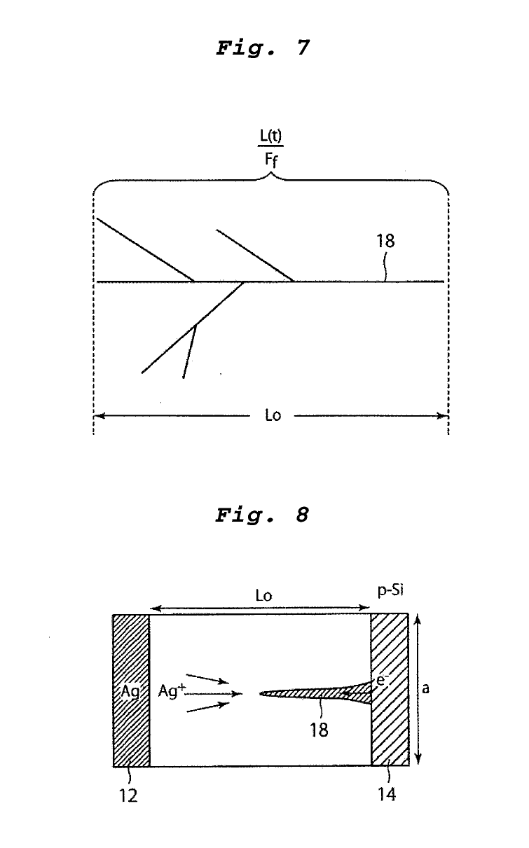

Meanwhile, since the actual filament length is L₀/F_{f}, the actual filament length is estimated to be 8 μm when the distance between the electrodes is 80 nm (e.g., L₀ in FIGS. 7 and 8). That is, the Ag filament formed in the amorphous silicon is not only from multiple thin amorphous filaments, but it is also surmised to have many branches as shown in FIG. 7. Due to this, the area of the Ag filament that is actually connected to the Ag electrode is also about 1% of the surface area of the Ag electrode. If this filament is disconnected, the resistance of the variable resistance layer substantially increases, which is likely to cause a considerable degradation in the reliability of the repeat characteristics, etc., and the data preservation characteristics as well. Therefore, the ability to form a single thick linear filament, such as the filament depicted in FIG. 8, could improve the characteristics of this device.

Hereinafter, a structure in which multiple dendrite-like Ag filaments are collected will be referred to as an Ag cluster. If the structure of the Ag cluster is assumed to be approximately wedge shaped and it is assumed that no Ag ions will enter into the cluster, then the diffusion equation (Laplace equations) of the Ag ions will be precisely solvable, and it will be possible to derive the distribution u(r, θ) of the Ag ions by the following equation, where the origin is assumed to be at the tip of the growing Ag cluster in which the Ag ion distribution is represented in the (r, θ) coordinate system.

$$u ( r , θ ) ∝ {r}^{π / 2 β} cos ( \frac{πθ}{2 β} ) \qquad ( 7 )$$

In light of equation 7, the adsorption probability P_{g} (rₛ) of the Ag ions cluster surface will be given by the following equation, where \vec{n} is a vector of unit length being normal to the surface of the Ag filament:

$${p}_{g} ( {\vec{r}}_{s} ) ∝ \vec{n} \cdot ∇ u ( {\vec{r}}_{s} ) = \frac{π {r}_{s}^{π / 2 β - 1}}{2 {β ( \frac{L ( t )}{cos ( π - β )} )}^{π / 2 β}} \qquad ( 8 )$$

In addition, if the number of Ag atoms in the cluster is N and the number of Ag atoms on the cluster tip is z, it is expected that the Ag⁺ adsorbed at the cluster surface (0≦rₛ≦(a/z cos(π−β)) contribute to the growth of the cluster. Here, one side of the cross-sectional area of the Ag cluster structure, which is a collection of 11 of the crystal structures shown in FIG. 5, is 2(2)^{1/2} a_{Si}×(11)^{1/2}=5 nm. That is, the cross-sectional area is equal to the value of the effective electrode reaction cross-sectional area S_{f} that is obtained by calculation. Therefore, in this embodiment a₀=(2)^{1/2}a_{Si}/4, z=11.

In addition, the probability of cluster growth Q(L(t)) is shown below.

$${Q}^{N} ( L ( t ) ) = \text{?} = {( \frac{{a}_{0}}{zL ( t )} )}^{π / 2 β} \\ \text{?} \text{indicates text missing or illegible when filed} \qquad ( 9 )$$

From this, N can be determined by solving the following growth equations of the cluster.

$$\frac{d L ( t )}{d N} = {Q}^{N} ( L ( t ) ) \frac{{a}_{0}}{z} \\ N = \frac{1}{\frac{π}{2 β} + 1} {( \frac{zL ( t )}{{a}_{0}} )}^{π / 2 β + 1} = \frac{1}{D} {( \frac{zL ( t )}{{a}_{0}} )}^{D} \qquad ( 10 )$$

Consequently, since the effective length of the Ag filament inside the cluster can be given by L₀/F_{f}=Na₀/z, the percentage of the electrode involved in the effective reaction cross-sectional area F_{f} can be written as follows:

$$\frac{1}{{F}_{f}} = \frac{1}{D} {( \frac{{zL}_{0}}{{a}_{0}} )}^{D - 1} \\ ( {L}_{0} \text{:} Distance between the electrodes ) \qquad ( 11 )$$

Actually, it will be understood that D=1.6 if the fractal dimension D is obtained for F_{f}=10⁻².

In addition, the angle β shown in FIG. 9 is approximately 150°, and it is shown that the angle formed by the tip of the Ag cluster is 60°. That is, it is expected that the Ag ions are adsorbed into the cluster from the normal direction of the cluster boundary. Stated differently, Ag ions are absorbed in a direction perpendicular to the leftmost dotted line shown in FIG. 9; the cluster expands towards the Ag electrode and also widens in the sideways direction, while preserving the tip angle of 60°. Thus, it can be concluded that the cross-sectional area of the Ag filament (effective electrode reaction cross-sectional area) that is actually connected to the Ag electrode is about 1% of the surface area of the electrode.

Due to this, when the cell width is a (see FIG. 8), as the aspect ratio (L₀/a) of the variable resistance layer 16 is increased, it will become possible for the value of the fractal dimension of the Ag cluster to approach unity (linear growth), making highly reliable memory operations possible.

Here, for the non-volatile resistance change device related to this embodiment, the device is configured so that switching time t_{sw} will be longer than the movement time of the Ag ions between the electrodes. This arrangement is described by the following relationship, in which V is the voltage applied across the first and second electrode (operating voltage).

$$\frac{{L}_{0}}{{μ}_{{Ag}^{+}} V / {L}_{0}} = \frac{{L}_{0}^{2}}{{μ}_{{Ag}^{+}} V} < {t}_{SW} . \qquad ( 12 )$$

That is, the distance between the electrodes L₀ will be within the range shown in equation below.

L₀<\sqrt{μ_{Ag}_{⁺}t_{SW}V} (13)

Also, if a and L₀ satisfy the following relationship (which occurs when the aspect ratio is sufficiently large), it will be possible to suppress the growth of the Ag filament in the sideways direction.

$$\frac{\sqrt{3}}{2} a = {tan ( 30 )}^{- 1} \frac{a}{2} < {L}_{0} \qquad ( 14 )$$

From equations (13) and (14), if the distance between the electrodes L₀ is designed to be in the range shown in the following equation (15), the linearity of the Ag filament formed inside the variable resistance layer will be increased and the characteristics of this device will vastly improve.

$$\frac{\sqrt{3}}{2} a < {L}_{0} < \sqrt{{μ}_{{Ag}^{+}} {t}_{SW} V} \qquad ( 15 )$$

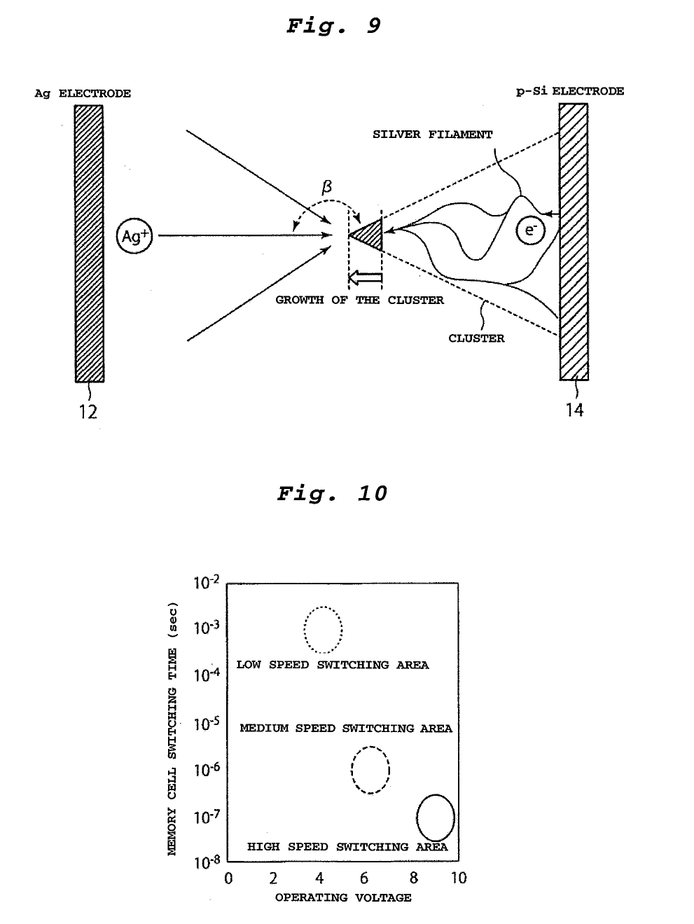

Next, the scope of design will be defined by describing three unique applications of the solid-state switch, where each application has a low, medium or high speed, as shown in FIG. 10.

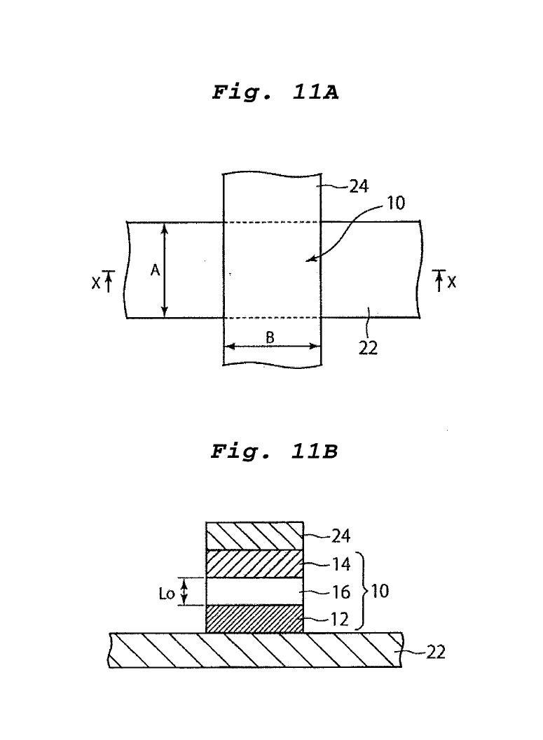

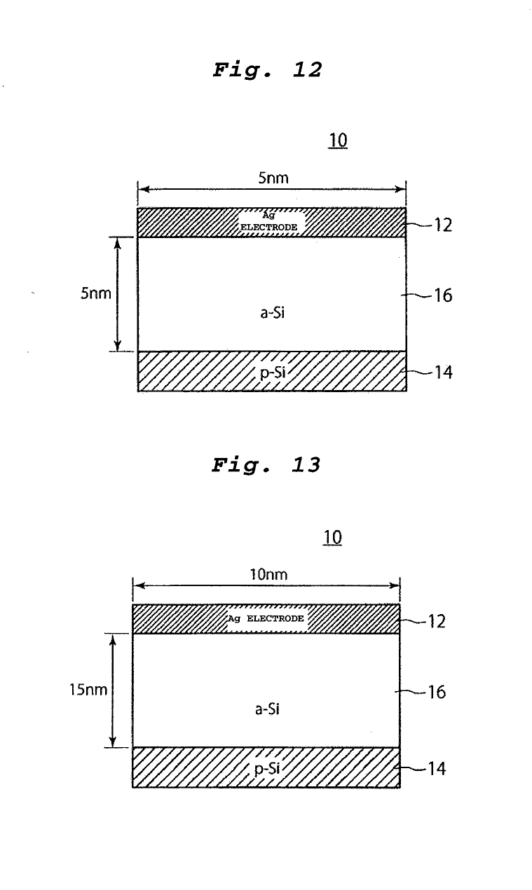

(1) In solid-state high speed switch devices used for SSD (Solid-state Drive), a minimum operating speed of 100 ns and an operating voltage of 9 V are required. As shown in FIG. 11A and FIG. 11B, for the resistance change device 10 used as a solid-state high speed switch device, if the widths of the wirings 22 and 24 attached to the top and bottom of the resistance change device 10 are A (nm) and B (nm), respectively, and the distance between the electrodes is L₀, it is desirable that A, B and L satisfy the following equation (17). Here, the wiring 22 and 24 is connected to the first electrode 12 and to the second electrode 14, respectively. Also, wiring width A is the maximum width of the area of the wiring 22 that is in contact with the first electrode 12. Wiring width B is the maximum width of the area of the wiring 24 that is in contact with the second electrode 14. In general, as shown in FIG. 11A, since the resistance change device 10 is set up at the intersection region of the two intersecting straight wires 22 and 24, the maximum width will be the width of the wiring. Stated differently, wiring width A will be the width of the wiring connected to the first electrode 12 and wiring width B will be the width of the wiring connected to the second electrode. Also, when the first electrode 12 serves as wiring 22 and the second electrode 14 serves as wiring 24, the wiring width A will be the width of the first electrode 12 and the wiring width B will be the width of the second electrode 14.

Here, since the value a, which represents the square root of the typical cross-section of the variable resistance layer 16, is a square root of the cross-sectional area, it can be,

a=(AB)^{1/2} (16)

Also, the square root of the cross-sectional area S of the variable resistance layer 16 can be used as the value of a. In this case, a=(S)^{1/2}.

As understood from equations (15) and (16), a non-volatile resistance change device based on the first aspect of this embodiment satisfies the following equation (17).

$$\frac{\sqrt{3}}{2} \sqrt{AB} < {L}_{0} \leq 6.7 \qquad ( 17 )$$

(2) In the case of solid-state medium speed switch devices used for memory card applications, because an operating speed of at least 1 μs and an operating voltage of 6 V are required, when the resistance change device 10 is employed, it is desirable that parameters A, B, and L₀ satisfy the following equation (18). A resistance change device based on the second aspect of this embodiment is a non-volatile resistance change device which satisfies this relationship.

$$6.7 < \frac{\sqrt{3}}{2} \sqrt{AB} < {L}_{0} \leq 17 \qquad ( 18 )$$

(3) When the resistance change device 10 is used as a solid-state low speed switch device for mobile applications, because an operating speed of at least 1 ms and an operating voltage of 4 V are required, it is desirable that A, B and L₀ satisfy the following equation (19). The third aspect of this embodiment provides a non-volatile resistance change device which satisfies this relational equation.

$$17 < \frac{\sqrt{3 }}{2} \sqrt{AB} < {L}_{0} \leq 45 \qquad ( 19 )$$

In addition, in equation (15), it is also possible to take the square root of the cross-sectional area S of the variable resistance layer 16 as the value of a. That is, it is also possible to make a=(S)^{1/2}. In this case, in equation (17), equation (18) and equation (19), (AB)^{1/2} will be replaced by (S)^{1/2}. In this case, equation (17) will be:

$$\frac{\sqrt{3}}{2} \sqrt{S} < {L}_{0} \leq 6.7 \qquad ( 20 )$$

Equation (18) will be:

$$6.7 < \frac{\sqrt{3}}{2} \sqrt{S} < {L}_{0} \leq 17 \qquad ( 21 )$$

Equation (19) will be:

$$17 < \frac{\sqrt{3}}{2} \sqrt{S} < {L}_{0} \leq 45 \qquad ( 22 )$$

The embodiments will be described below.

### Embodiment 1

The non-volatile resistance change device (also known as resistance change device, below) provided by the first embodiment is shown in FIG. 12. The resistance change device 10 of this first embodiment has a structure that includes an Si substrate (p-Si substrate) doped with B (Boron) in high concentrations configured as the lower electrode 14 (also called the second electrode), an Ag electrode configured as the upper electrode 12 (also called the first electrode), and a variable resistance layer 16, located between the upper electrode 12 and lower electrode 14. In addition, for this embodiment and the second to fifth embodiments described below, the resistance change device 10 incorporates lamination of the second electrode 14, the variable resistance layer 16 and the first electrode 12 in that order. However, as will be described later, for the resistance change device of Embodiment 6, the order of lamination can be in the reverse order, that is, with lamination of the first electrode 12, the variable resistance layer 16 and the second electrode.

In the case of Embodiment 1, in the lower electrode 14, for example, for the resistivity of the electrode to become 0.005 Ωcm or lower, high concentrations of B are injected. For the lower electrode 14, it is possible to use n-Si substrates or the metals Ti, Ni, Co, Fe, Cr, Cu, W, Hf, Ta, Pt, Ru, Zr or Ir, etc., their nitrides or carbides, chalcogenide materials, etc. Since it is desirable for the second electrode 14 to be composed of a material which is more difficult to ionize relative to the first electrode 12, the following sections will describe the case related to a p-Si substrate.

In this embodiment, the layer thickness of the amorphous silicon, which is the variable resistance layer 16 between the upper electrode 12 and lower electrode 14, is 5 nm and the area of the electrodes 12 and 14 is 25 nm². The resistance change device 10 of this first embodiment is a resistance change device that satisfies equation (17).

Next, the production method of the structure shown in this embodiment will be described. At first, the lower electrode is made by forming a p-Si substrate. Formation of the p-Si substrate involves injecting B ions, for example, using an accelerating voltage of 30 keV and a dosage of 2×10¹⁵ cm⁻², then applying activated annealing to a silicon single crystal substrate. Next, an amorphous silicon layer is deposited to serve as the variable resistance layer 16, for example, by Plasma-Enhanced Chemical Vapor Deposition (Plasma-Enhanced Chemical Vapor Deposition: PECVD). At this time, it is possible to modify the dangling bond density ratio in the amorphous silicon layer by regulating the flow rate ratio of the monosilane molecules (SiH₄) and hydrogen, which are the raw material gases. Also, it is possible to minimize the dangling bond density of the gaps by optimizing the hydrogen flow rate. Moreover, at the same time, it is possible to lower the Si density of the amorphous silicon layer to be generated by increasing the pressure inside the chamber during film making. It is possible to verify the Si density of the amorphous silicon layer by XRR Measurement (X-Ray Reflectivity Measurement), and it is also possible to adjust the Si density of the amorphous silicon layer. For the upper electrode, it is possible to prepare an Ag electrode by vapor deposition.

In the resistance change device 10 of the first embodiment, formed in this manner, it is possible to carry out the operations of creating and destroying the Ag filament in a reversible manner, at high speeds, and in a stable manner.

As described above, according to this embodiment, it is possible to form a non-volatile resistance change device in which highly reliable switching operations are possible.

### Embodiment 2

The non-volatile resistance change device based on the second embodiment is shown in FIG. 13. The resistance change device 10 of the second embodiment differs in size from the non-volatile resistance change device of the first embodiment, and in the second embodiment the layer thickness of the amorphous silicon, which serves as the variable resistance layer 16 between the upper electrode 12 and lower electrode 12, is 15 nm. The electrode area in the second embodiment is 100 nm̂2. Moreover, the resistance change device 10 of this second embodiment is configured so as to satisfy equation (18).

Similar to the first embodiment, for the non-volatile resistance change device 10 of the second embodiment, it is possible to carryout the operations of creating and destroying the Ag filament in a reversible and a stable manner.

As described above, according to the second embodiment, it is possible to form a non-volatile resistance change device in which highly reliable switching operations are possible.

### Embodiment 3

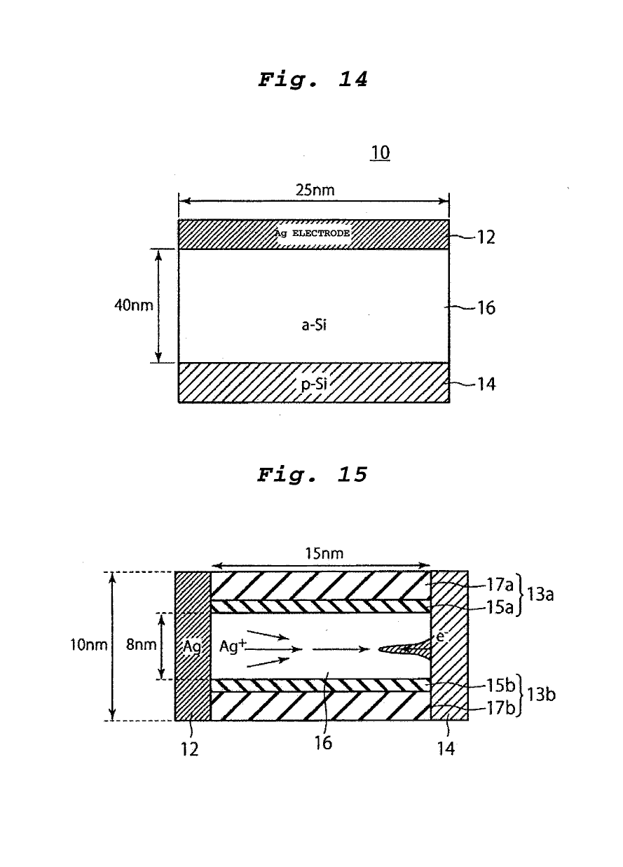

The non-volatile resistance change device based on the third embodiment is shown in FIG. 14. The resistance change device 10 of the third embodiment differs in size from the non-volatile resistance change device of the first embodiment. In the third embodiment the layer thickness of the amorphous silicon, which serves as the variable resistance layer 16, is 40 nm. Additionally, the electrode area is 525 nm². The third embodiment is a resistance change device having parameters which satisfy equation (19).

Similar to the first embodiment, for the non-volatile resistance change device 10 of the third embodiment, it is possible to carryout the operations of creating and destroying the Ag filament in a reversible and stable manner.

As described above, according to the third embodiment, it is possible to form a non-volatile resistance change device in which highly reliable switching operations are possible.

### Embodiment 4

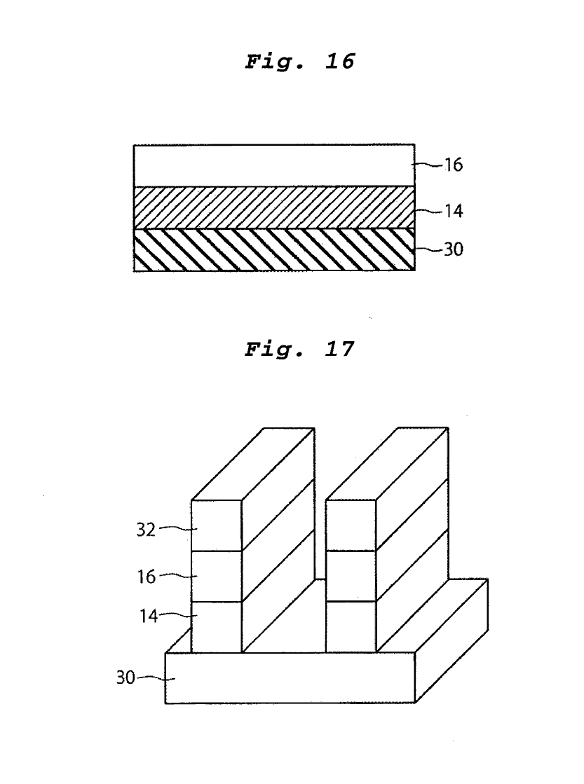

The non-volatile resistance change device based on the fourth embodiment will be described. The fourth embodiment involves modification of the non-volatile resistance change device of the second embodiment. As shown in FIG. 15, the modification of the second embodiment is done by forming, in the amorphous silicon variable resistance layer 16, barrier layers 13a, 13b having Silicon Nitride films 15a, 15b and silicon oxide films 17a, 17b. Silicon nitride films 15a, 15b are formed sandwiching the opposite sides of the variable resistance layer 16, and on the outer sides of these silicon nitride films 15a, 15b opposite to the variable resistance layer 16, silicon oxide films 17a, 17b are formed respectively. Due to the formation of such barriers 13a, 13b at the sides of the variable resistance 16, effectively, it is possible to reduce the Ag ion conduction area.

If the structure similar to that of the fourth embodiment is formed, the aspect ratio of the variable resistance layer 16 can effectively be increased so as to exceed the aspect ratio of the second embodiment, and it will be possible to realize a more reliable switching operation. In addition, the miniaturization of the device can also be expected by shortening of the distance between the electrodes. Here, the silicon nitride films 15a, 15b are layers which are formed so that the Ag ions do not pierce through them, and any other layers that possess the same effects can also be so used.

Next, the production method of the structure shown in this embodiment is described using FIG. 16 to FIG. 23 as a reference. First, a metal wiring layer, for example, a W layer, which will be the second electrode 14, is formed on top of the silicon oxide film 30. Following that, an amorphous silicon layer which will be the variable resistance layer 16 is deposited on top of the metal wiring layer 14, for example, by the Plasma-enhanced Chemical Vapor Deposition (PECVD) method (FIG. 16).

Next, an oxide film mask 32 is formed on top of the amorphous silicon layer 16 by forming an oxide film layer 32 and patterning the oxide film layer 32 using lithography technology. By using this mask 32, anisotropic etching of the amorphous silicon layer 16 and the metal wiring layer 14 is carried out to form multiple laminated structures. Laminating is done in the order of metal wiring layer 14, amorphous silicon layer 16 and mask 30, as shown in FIG. 17. Each laminated structure exposes sides of amorphous silicon layers 16 on pairs of its opposing sides.

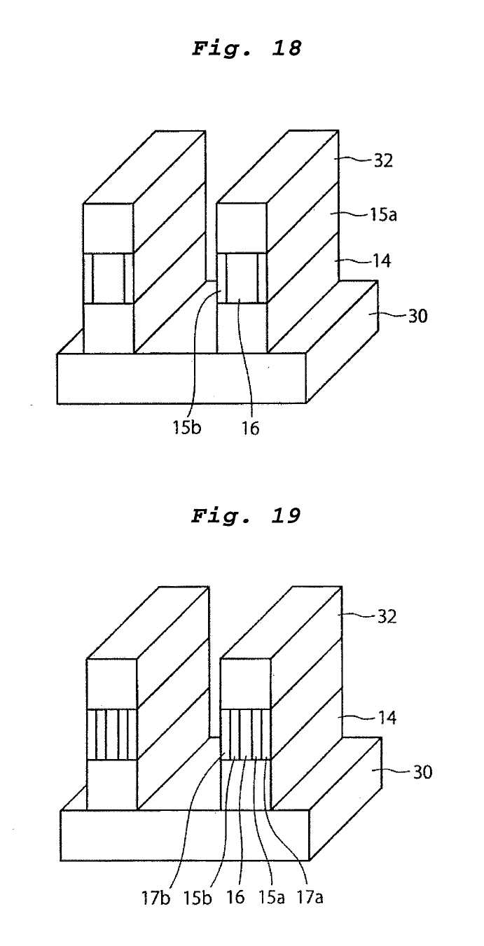

Continuing, as shown in FIG. 18, the plasma nitriding process is carried out on the exposed pairs of sides of the exposed amorphous silicon layer 16, forming nitride films 15a, 15b on each of the above-mentioned pairs of exposed opposing sides of the amorphous silicon layer 16. Then, by carrying out the Plasma oxidizing process, the oxide films 17a, 17b are formed on the surfaces of the nitride films 15a, and 15b opposite to the amorphous silicon layer 16, as shown in FIG. 19.

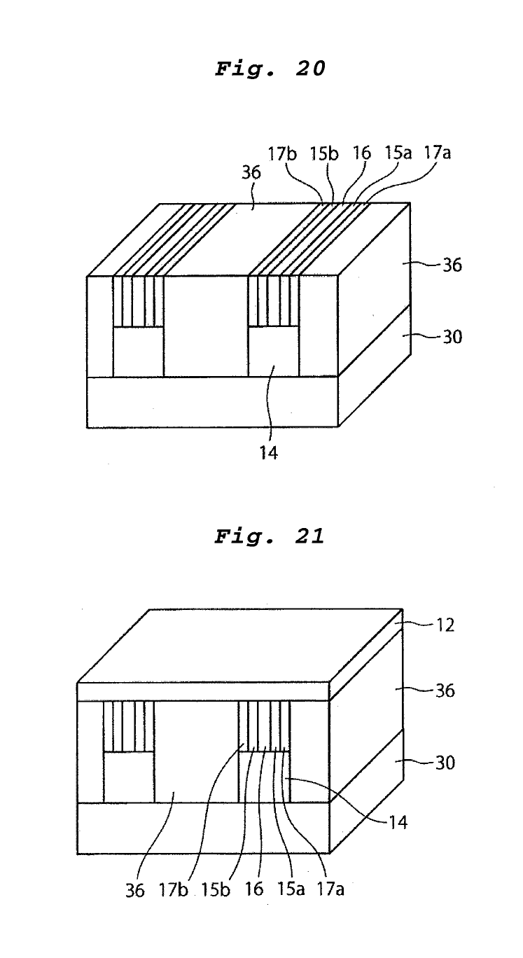

Next, after depositing an oxide film 36 in order to fill the spaces in the laminated structure, its flattening is carried out by CMP, and, if necessary, by etching the oxide film 36 and the mask 32, so that the top surface of the amorphous silicon layer 16 is exposed (FIG. 20). The Ag upper electrode 12 is formed by carrying out Ag vapor deposition in order to cover the exposed top surface of the amorphous silicon 16 (FIG. 21).

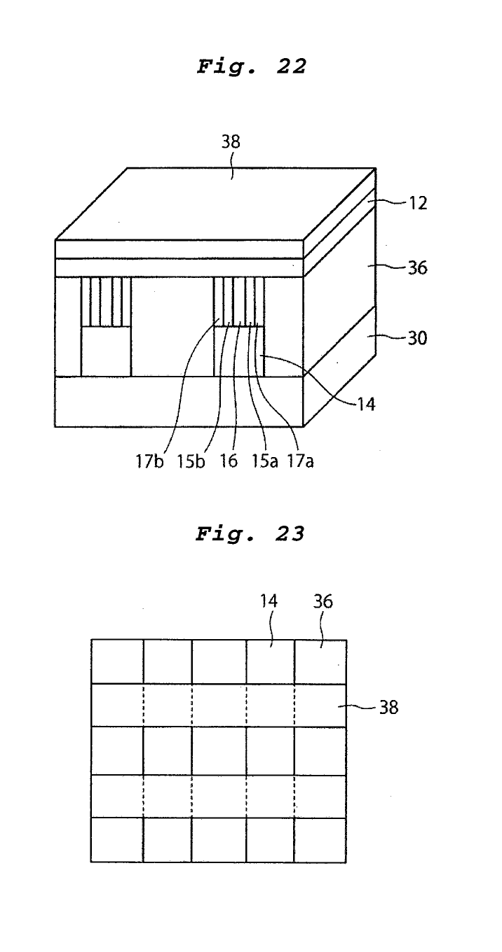

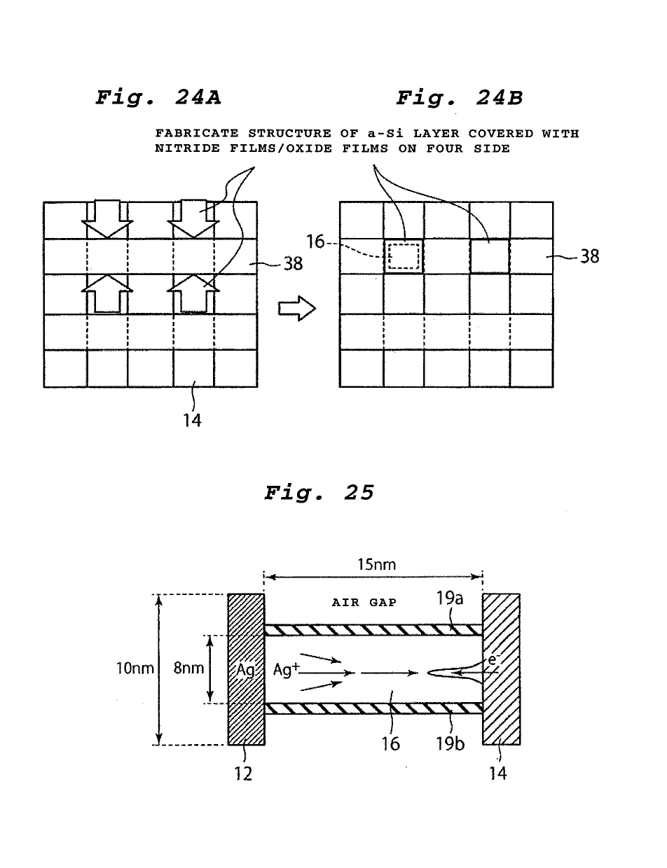

In addition, an oxide film 38 is laminated so that the upper electrode 12 is covered, as shown in FIG. 22. Then, for example, a photo resist mask is formed (not shown in the FIG.) on top of the oxide film 38; using this resist mask, patterning is carried out using lithography technology until the top of the metal wiring 14 is exposed. When this is done, as shown in the top view diagram of FIG. 23, patterns are obtained that are arranged such that the Ag upper electrode 12 directly under the oxide film 38 is orthogonal to the lower electrode of metal wiring 14. At this time a resistance change device is formed at the intersecting region of the lower electrode 14 and upper electrode 12. The resistance change device has a variable resistance layer 16 formed of a patterned amorphous silicon layer. The variable resistance layer 16 of this resistance change device is exposed on the side which is parallel to the extended direction of the upper electrode 12, that is, the extended direction of the oxide film 38. Continuing, as shown in FIG. 24A, plasma oxidation is carried out after carrying out plasma nitriding. When this is done, the variable resistance layer 16 becomes covered by a silicon nitride film/silicon oxide film on the side which is parallel to the extended direction of the upper electrode 12, that is, the extended direction of the oxide film 38. Due to this, a resistance change device is formed with a variable resistance layer 16 formed of an amorphous silicon layer whose 4 sides are covered in silicon nitride films/silicon oxide films, as shown in FIG. 24B, making a cross point type of memory achievable.

In the resistance change device 10 of the fourth embodiment, which is also formed in this manner, it is possible to carry out the operations of creating and destroying the Ag filament in a reversible manner, at high speeds, and in a stable manner.

As described above, according to the fourth embodiment, it is possible to form a non-volatile resistance change device in which highly reliable switching operations are possible.

### Embodiment 5

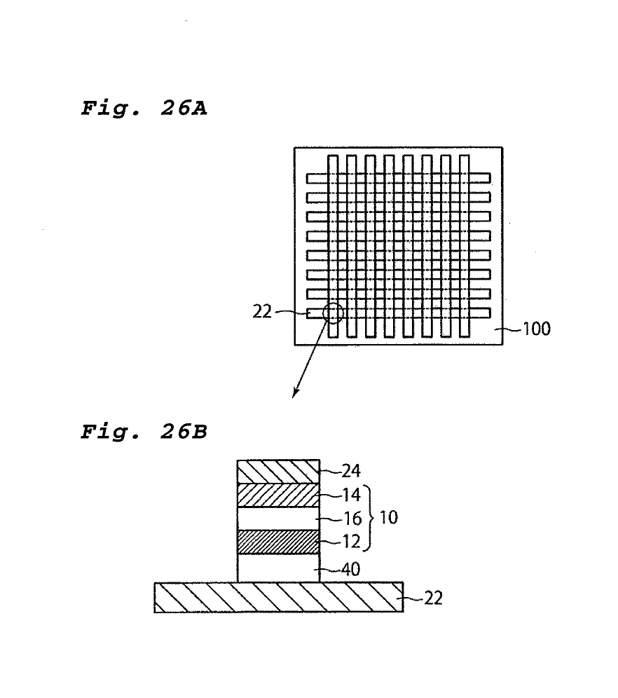

The non-volatile resistance change device based on the fifth embodiment is shown in FIG. 25. In comparison to the non-volatile resistance change device of the fourth embodiment shown in FIG. 15, this fifth embodiment uses barrier layers 19a, 19b formed of silicon nitride films/air gaps or silicon oxide films/air gaps instead of the barrier layers 13a, 13b formed of silicon nitride films 15a, 15b/silicon oxide films 17a, 17b. By the usage of barriers like 19a, 19b not only is it possible to effectively reduce the Ag ion conduction area, but the production process also becomes simpler than the fourth embodiment.

In the resistance change device 10 of Embodiment 5, formed in this manner, it is possible to carry out the operations of creating and destroying the Ag filament in a reversible manner, at high speeds, and in a stable manner.

As described above, according to the fifth embodiments, it is possible to form a non-volatile resistance change device in which highly reliable switching operations are possible.

### Embodiment 6

The resistance change memory based on Embodiment 6 is shown in FIG. 26A and FIG. 26B. The resistance change memory of this sixth embodiment is a cross point memory; it has an array of multiple first wirings 22 arranged in parallel on the substrate 100, multiple second wirings 24 which intersect these first wirings 22, resistance change devices 10 formed in the intersecting regions between the first wirings 22 and second wirings 24 and rectification devices 40 formed between the resistance change devices 10 and first wirings 22. The resistance change device 10 has a first electrode 12 formed on top of the rectification device 40, a second electrode 14 which connects to the second wiring, and a variable resistance layer 16 formed between the first electrode 12 and second electrode 14.

In addition, the resistance change devices shown in FIG. 15 or FIG. 25 can also be used as the resistance change device 10 in this embodiment.

As described above, according to this embodiment, it is possible to form a memory with a non-volatile resistance change device in which highly reliable switching operations are possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile resistance change device comprising:
a first electrode which includes a metallic element;
a second electrode;
a variable resistance layer formed between the first electrode and the second electrode;
a first wiring formed on the first electrode on a side opposite to the variable resistance layer; and
a second wiring formed on the second electrode on a side opposite to the variable resistance layer,
wherein the following equation is satisfied:
$$\frac{\sqrt{3}}{2} \sqrt{AB} < {L}_{0} \leq 6.7$$
where the width of the first wiring is A (nm), width of the second wiring is B (nm), and the distance between the first electrode and the second electrode is L₀ (nm).

2. The non-volatile resistance change device of claim 1, wherein the metallic element of the first electrode is silver and the metallic element ionizes when a first differential voltage is applied across the first and second electrode, and wherein the ionization produces ions which migrate towards the second electrode.

3. The non-volatile resistance change device of claim 2, wherein the migration results in a conductive filament cluster being formed between the first and second electrodes, and wherein at a second electrode surface which faces the variable resistance layer, the filament cluster has a cross-sectional area that is between 0.5% and 1.5% of the surface area of said second electrode surface.

4. The non-volatile resistance change device of claim 3, wherein the device is configured so that the filament buildup can be ruptured by applying a second differential voltage across the first and second electrodes.

5. A non-volatile resistance change device comprising:
a first electrode which includes a metallic element;
a second electrode;
a variable resistance layer formed between the first electrode and the second electrode;
a first wiring formed on the first electrode on a side opposite to the variable resistance layer;
a second wiring formed on the second electrode on aside opposite to the variable resistance layer,
wherein the following equation is satisfied:
$$6.7 < \frac{\sqrt{3}}{2} \sqrt{AB} < {L}_{0} \leq 17$$
where the width of the first wiring is A (nm), width of the second wiring is B (nm), and the distance between the first electrode and the second electrode is L₀ (nm).

6. The non-volatile resistance change device of claim 5, wherein the metallic element of the first electrode is silver and the metallic element ionizes when a first differential voltage is applied across the first and second electrode, and wherein the ionization produces ions which migrate towards the second electrode.

7. The non-volatile resistance change device of claim 6, wherein the migration results in a conductive filament cluster being formed between the first and second electrodes, and wherein at a second electrode surface which faces the variable resistance layer, the filament cluster has a cross-sectional area that is between 0.5% and 1.5% of the surface area of said second electrode surface.

8. The non-volatile resistance change device of claim 7, wherein the device is configured so that the filament buildup can be ruptured by applying a second differential voltage across the first and second electrodes.

9. A non-volatile resistance change device comprising:
a first electrode which includes a metallic element;
a second electrode;
a variable resistance layer formed between the first electrode and the second electrode;
a first wiring formed on the first electrode on a side opposite to the variable resistance layer;
a second wiring formed on the second electrode on a side opposite to the variable resistance layer,
wherein the following equation is satisfied:
$$17 < \frac{\sqrt{3}}{2} \sqrt{AB} < {L}_{0} \leq 45$$
where the width of the first wiring is A (nm), width of the second wiring is B (nm), and the distance between the first electrode and the second electrode is L₀ (nm).

10. The non-volatile resistance change device of claim 9, wherein the metallic element of the first electrode is silver and the metallic element ionizes when a first differential voltage is applied across the first and second electrode, and wherein the ionization produces ions which migrate towards the second electrode.

11. The non-volatile resistance change device of claim 10, wherein the migration results in a conductive filament cluster being formed between the first and second electrodes, and wherein at a second electrode surface which faces the variable resistance layer, the filament cluster has a cross-sectional area that is between 0.5% and 1.5% of the surface area of said second electrode surface.

12. The non-volatile resistance change device of claim 11, wherein the device is configured so that the filament buildup can be ruptured by applying a second differential voltage across the first and second electrodes.

13. A non-volatile resistance change device comprising:
a first electrode which includes a metallic element;
a second electrode;
a variable resistance layer formed between the first electrode and the second electrode,
wherein the following equation is satisfied:
$$\frac{\sqrt{3}}{2} \sqrt{S} < {L}_{0} \leq 6.7$$
where the cross-sectional area of the variable resistance layer is S (nm²) and the distance between the first electrode and the second electrode is L₀ (nm).

14. The non-volatile resistance change device of claim 13, wherein the metallic element of the first electrode is silver and the metallic element ionizes when a first differential voltage is applied across the first and second electrode, the ionization producing ions which migrate towards the second electrode.

15. The non-volatile resistance change device of claim 14, wherein the migration results in a conductive filament cluster being formed between the first and second electrodes, and wherein at a second electrode surface which faces the variable resistance layer, the filament cluster has a cross-sectional area that is between 0.5% and 1.5% of the surface area of said second electrode surface.

16. The non-volatile resistance change device of claim 15, wherein the device is configured so that the filament buildup can be ruptured by applying a second differential voltage across the first and second electrodes.

17. A non-volatile resistance change device comprising:
a first electrode which includes a metallic element;
a second electrode;
a variable resistance layer formed between the first electrode and the second electrode,
wherein the following equation is satisfied:
$$6.7 < \frac{\sqrt{3}}{2} \sqrt{S} < {L}_{0} \leq 17$$
where the cross-sectional area of the variable resistance layer is S (nm²) and the distance between the first electrode and the second electrode is L₀ (nm).

18. The non-volatile resistance change device of claim 17, further comprising:
barrier layers of insulation formed on the sides of the variable resistance layer, with the barrier layers located between the first electrode and second electrode.

19. A non-volatile resistance change device comprising:
a first electrode which includes a metallic element;
a second electrode;
a variable resistance layer formed between the first electrode and the second electrode,
wherein the following equation is satisfied:
$$17 < \frac{\sqrt{3}}{2} \sqrt{S} < {L}_{0} \leq 45$$
where the cross-sectional area of the variable resistance layer is S (nm²), the width of the second wiring is B (nm), and the distance between the first electrode and the second electrode is L₀ (nm).

20. The non-volatile resistance change device of claim 19, further comprising:
barrier layers of insulation formed on the sides of the variable resistance layer, with the barrier layers located between the first electrode and second electrode.
